(19) United States
(12) Patent Application Publication
(10) Pub. No.: US 2026/0164885 A1
(43) Pub. Date: Jun. 11, 2026

(54) DISPLAY DEVICE AND TILED DISPLAY DEVICE INCLUDING THE SAME

(71) Applicant: Samsung Display Co., Ltd., Yongin-si (KR)

(72) Inventor: Kye Uk LEE, Yongin-si (KR)

(21) Appl. No.: 19/179,879

(22) Filed: Apr. 15, 2025

(30) Foreign Application Priority Data
Jun. 26, 2024 (KR) 10-2024-0083417
Oct. 15, 2024 (KR) 10-2024-0140339

(51) Int. Cl. H10H 29/49; H10H 29/24; H10H 29/39; H10H 29/80; H10W 42/60

(52) U.S. Cl. CPC H10H 29/49; H10H 29/24; H10H 29/39; H10H 29/8321; H10W 42/60

(57) ABSTRACT

Provided are a display device and a tiled display device including the same. A display device includes a substrate, first electrodes above the substrate, second electrodes above the substrate, first pad electrodes respectively above the first electrodes, second pad electrodes respectively above the second electrodes, light-emitting elements respectively above the first pad electrodes and the second pad electrodes, a first source voltage layer connected to the second electrodes, and an electrostatic protection layer at an edge of at least one side of the substrate, and connected to the second pad electrodes and to the first source voltage layer.

### CROSS-REFERENCE TO RELATED APPLICATION

The present application claims priority to, and the benefit of, Korean Patent Application No. 10-2024-0083417, filed on Jun. 26, 2024, and Korean Patent Application No. 10-2024-0140339, filed on Oct. 15, 2024, in the Korean Intellectual Property Office, the entire disclosures of which are incorporated herein by reference.

### BACKGROUND

### 1. Field

One or more embodiments of the present disclosure relate to a display device and a tiled display device including the same.

### 2. Description of the Related Art

As the information society develops, the demand for display devices for displaying images has increased and diversified. The display devices may be flat panel display devices, such as liquid crystal displays (LCDs), field emission displays (FEDs), or light-emitting displays (LEDs). A light-emitting display device may include an organic light-emitting display device including organic light-emitting diode elements as light-emitting elements, or a light-emitting diode display device including inorganic light-emitting diode elements, such as light-emitting diodes (LEDs) as light-emitting elements.

### SUMMARY

Aspects of embodiments of the present disclosure provide a display device capable of stably discharging static electricity flowing into edges of the display device.

Aspects of embodiments of the present disclosure also provide a tiled display device capable of stably discharging static electricity flowing into edges of a display device.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a substrate, first electrodes above the substrate, second electrodes above the substrate, first pad electrodes respectively above the first electrodes, second pad electrodes respectively above the second electrodes, light-emitting elements respectively above the first pad electrodes and the second pad electrodes, a first source voltage layer connected to the second electrodes, and an electrostatic protection layer at an edge of at least one side of the substrate, and connected to the second pad electrodes and to the first source voltage layer.

The electrostatic protection layer may include a same material as the first pad electrodes and the second pad electrodes.

The first pad electrodes, the second pad electrodes, and the electrostatic protection layer may include a transparent conductive oxide.

The first source voltage layer may include a same material as the first electrodes and the second electrodes.

The first electrodes, the second electrodes, and the first source voltage layer may include an opaque metal material.

The electrostatic protection layer may include a first line portion at an edge of a first side of the substrate, and extending in a second direction, and a first contact portion extending from the first line portion in a first direction crossing the second direction, and contacting the first source voltage layer.

The electrostatic protection layer may further include a second line portion at an edge of a second side of the substrate that is adjacent to the first side, and extending in the first direction, and a second contact portion extending from the second line portion in the second direction, and contacting the first source voltage layer.

A length of the first contact portion in the first direction may be less than a length of the second contact portion in the second direction.

The display device may further include pixels including L first electrodes of the first electrodes and L second electrodes of the second electrodes may be defined above the substrate, L being an integer of 2 or more.

The electrostatic protection layer may further include a first electrode contact portion extending from the first line portion, and contacting the second electrodes of a first one of the pixels adjacent to the first line portion.

The first electrode contact portion may be connected to one side of the second electrodes of the first one of the pixels.

The first electrode contact portion may surround at least one of the first electrodes of the first one of the pixels.

One of the first electrodes adjacent to the first line portion of the first one of the pixels may be surrounded by the first line portion and the first electrode contact portion.

The first electrodes, other than one of the first electrodes adjacent to the first line portion of the first one of the pixels, may be surrounded by the first electrode contact portion.

The electrostatic protection layer may further include a second electrode contact portion extending from the second contact portion, and contacting the second electrodes of a second one of the pixels that is adjacent to the second line portion.

The second electrode contact portion may be connected to a first side of the second electrodes of the second one of the pixels, and a second side of the second electrodes of the second one of the pixels faces the second line portion.

One side of the first electrodes of the second one of the pixels may be exposed without being surrounded by the second electrode contact portion.

According to one or more embodiments of the present disclosure, there is provided a tiled display device including display devices, and a seam portion between the display devices, wherein one of the display devices includes a substrate, first electrodes above the substrate, second electrodes above the substrate, first pad electrodes respectively above the first electrodes, second pad electrodes respectively above the second electrodes, light-emitting elements respectively above the first pad electrodes and the second pad electrodes, a first source voltage layer connected to the second electrodes, and an electrostatic protection layer at an edge of at least one side of the substrate, and connected to the second pad electrodes and the first source voltage layer.

The substrate may include glass.

The one of the display devices may further include a side surface line on a side surface between a first surface of the substrate, and a second surface opposite to the first surface, a bottom surface line on the second surface of the substrate, and a circuit board connected to the bottom surface line through a conductive adhesive member.

The display devices may be arranged in a matrix form in M rows and N columns, M and N respectively being integers of 2 or more.

According to one or more embodiments of the present disclosure, there is provided an electronic device including a display device including a substrate, first electrodes above the substrate, second electrodes above the substrate, first pad electrodes respectively above the first electrodes, second pad electrodes respectively above the second electrodes, light-emitting elements respectively above the first pad electrodes and the second pad electrodes, a first source voltage layer connected to the second electrodes, and an electrostatic protection layer at an edge of at least one side of the substrate, and connected to the second pad electrodes and to the first source voltage layer.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.

According to the aforementioned and other embodiments of the present disclosure, static electricity flowing into a first line portion and a second line portion of edges of a display panel may be discharged to a first source voltage layer through a first contact portion and a second contact portion. In addition, static electricity flowing into first pixels and second pixels adjacent to the edges of the display panel may be discharged to the first source voltage layer through a first electrode contact portion and a second electrode contact portion. Furthermore, static electricity flowing into third pixels located at a central portion of the display panel, rather than the edges of the display panel, may also be discharged to the first source voltage layer through a third electrode contact portion. Therefore, static electricity flowing into areas adjacent to light-emitting elements on a front surface of the display panel may be stably discharged to the first source voltage layer.

### BRIEF DESCRIPTION OF THE DRAWINGS

The above and other aspects of the present disclosure will become more apparent by describing embodiments thereof with reference to the attached drawings, in which:

FIGS. 1 and 2 are perspective views illustrating a display device according to one or more embodiments;

FIG. 3 is a layout diagram illustrating a portion of a front surface of a display panel according to one or more embodiments;

FIG. 4 is an enlarged layout diagram illustrating area A of FIG. 3 in detail;

FIG. 5 is an enlarged layout diagram illustrating area B of FIG. 3 in detail;

FIG. 6 is an enlarged layout diagram illustrating area C of FIG. 3 in detail;

FIG. 7 is a cross-sectional view illustrating an example of a cross section of the display panel taken along the line I1-I1′ of FIG. 4;

FIG. 8 is a cross-sectional view illustrating an example of a cross section of the display panel taken along the line I2-I2′ of FIG. 4;

FIG. 9 is a cross-sectional view illustrating an example of a cross section of the display panel taken along the line I3-I3′ of FIG. 3;

FIG. 10 is a perspective view illustrating a tiled display device including a plurality of display devices according to one or more embodiments;

FIG. 11 is an enlarged layout diagram illustrating area Y of FIG. 10 in detail; and

FIG. 12 is a cross-sectional view illustrating an example of the tiled display device taken along the line N-N′ of FIG. 11.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

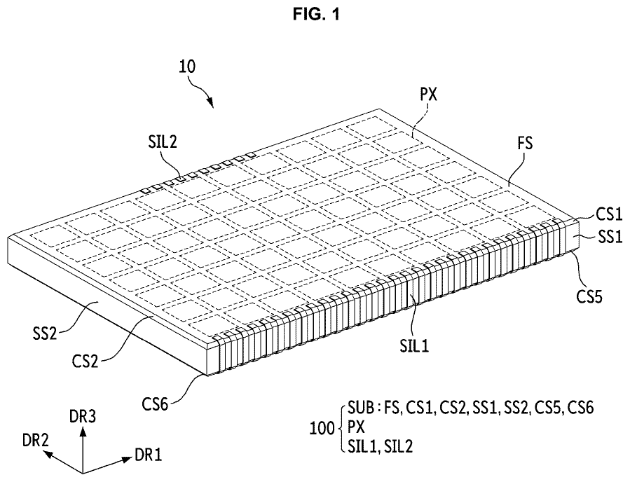

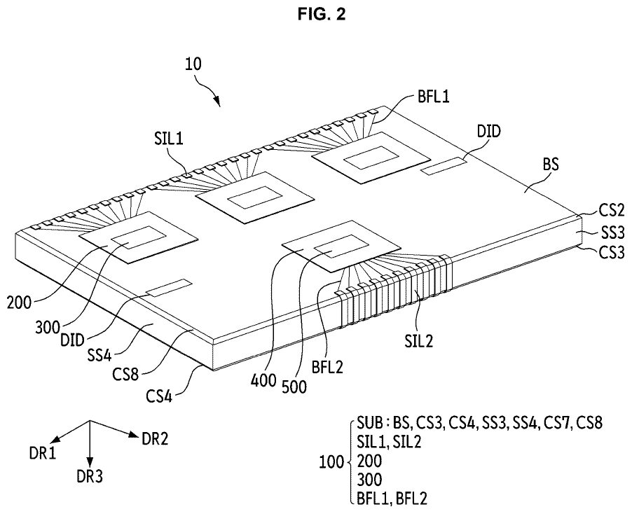

FIGS. 1 and 2 are perspective views illustrating a display device according to one or more embodiments.

Referring to FIGS. 1 and 2, a display device 10 according to one or more embodiments is a device that displays a moving image or a still image, and may be used as a display screen of various products, such as televisions, laptop computers, monitors, billboards, and the Internet of Things (IOT) devices as well as portable electronic devices, such as mobile phones, smartphones, tablet personal computers (PCs), smart watches, watch phones, mobile communication terminals, electronic notebooks, electronic books, portable multimedia players (PMPs), navigation devices, ultra mobile PCs (UMPCs), head-mounted displays (HMD), virtual reality (VR) devices, or augmented reality (AR) devices.

The display device 10 according to one or more embodiments may include a display panel 100, circuit boards 200, and source drivers 300.

The display panel 100 may include a substrate SUB, first bottom surface fan-out lines BFL1, second bottom surface fan-out lines BFL2, a plurality of pixels PX, a plurality of first side surface lines SIL1, a plurality of second side surface lines SIL2, and a plurality of device identifiers DID.

The substrate SUB may include a first surface FS, a second surface BS, a plurality of chamfered surfaces CS1 to CS8, and a plurality of side surfaces SS1 to SS4.

The first surface FS may be a front surface of the substrate SUB. The first surface FS may have a rectangular shape having long sides in a first direction DR1, and short sides in a second direction DR2.

The second surface BS may be a surface opposing the first surface FS. The second surface BS may be a back surface of the substrate SUB. The second surface BS may have a rectangular shape having long sides in the first direction DR1, and short sides in the second direction DR2.

The plurality of chamfered surfaces CS1 to CS8 refer to obliquely chamfered surfaces located between the plurality of side surfaces SS1 to SS4 and the first surface FS or the second surface BS to reduce or prevent chipping defects occurring in the plurality of first side surface lines SIL1 and the plurality of second side surface lines SIL2. A bending angle of each of the plurality of first side surface lines SIL1 and the plurality of second side surface lines SIL2 may become relatively gentle or gradual due to the plurality of chamfered surfaces CS1 to CS8, and it is thus possible to reduce or prevent chipping or cracks from occurring in the plurality of first side surface lines SIL1 and the plurality of second side surface lines SIL2.

A first chamfered surface CS1 may extend from a first side, for example, a lower side, of the first surface FS. A second chamfered surface CS2 may extend from a second side, for example, a left side, of the first surface FS. A third chamfered surface CS3 may extend from a third side, for example, an upper side, of the first surface FS. A fourth chamfered surface CS4 may extend from a fourth side, for example, a right side, of the first surface FS. An internal angle formed by the first surface FS and the first chamfered surface CS1, an internal angle formed by the first surface FS and the second chamfered surface CS2, an internal angle formed by the first surface FS and the third chamfered surface CS3, and an internal angle formed by the first surface FS and the fourth chamfered surface CS4 may be greater than about 90°.

A fifth chamfered surface CS5 may extend from a first side, for example, a lower side, of the second surface BS. A sixth chamfered surface CS6 may extend from a second side, for example, a left side, of the second surface BS. A seventh chamfered surface CS7 may extend from a third side, for example, an upper side, of the second surface BS. An eighth chamfered surface CS8 may extend from a fourth side, for example, a right side, of the second surface BS. An internal angle formed by the second surface BS and the fifth chamfered surface CS5, an internal angle formed by the second surface BS and the sixth chamfered surface CS6, an internal angle formed by the second surface BS and the seventh chamfered surface CS7, and an internal angle formed by the second surface BS and the eighth chamfered surface CS8 may be greater than about 90°.

A first side surface SS1 may extend from the first chamfered surface CS1. The first chamfered surface CS1 may be located between the first surface FS and the first side surface SS1. The first side surface SS1 may be a lower side surface of the substrate SUB.

A second side surface SS2 may extend from the second chamfered surface CS2. The second chamfered surface CS2 may be located between the first surface FS and the second side surface SS2. The second side surface SS2 may be a left side surface of the substrate SUB.

A third side surface SS3 may extend from the third chamfered surface CS3. The third chamfered surface CS3 may be located between the first surface FS and the third side surface SS3. The third side surface SS3 may be an upper side surface of the substrate SUB.

A fourth side surface SS4 may extend from the fourth chamfered surface CS4. The fourth chamfered surface CS4 may be located between the first surface FS and the fourth side surface SS4. The fourth side surface SS4 may be a right side surface of the substrate SUB.

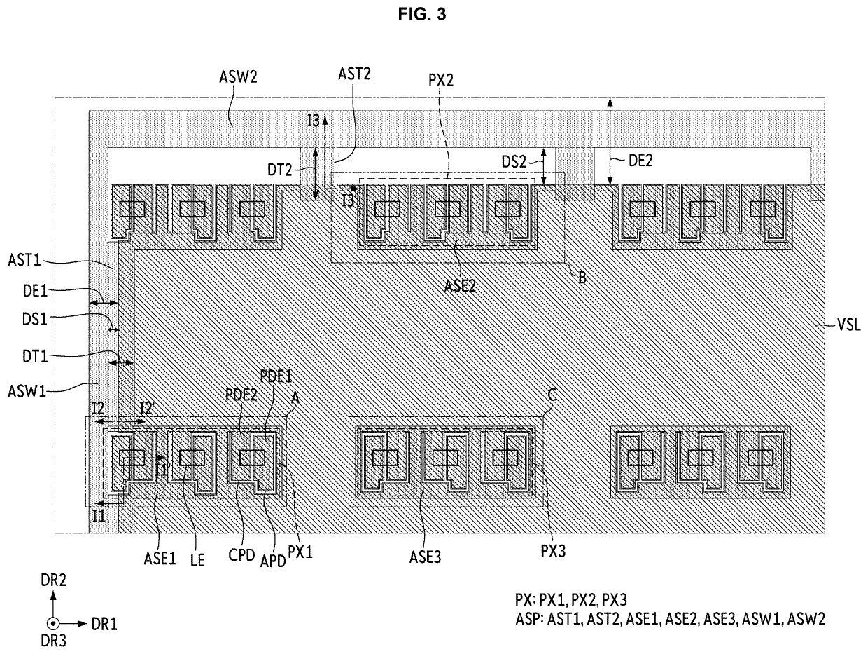

The plurality of pixels PX may be located on the first surface FS of the substrate SUB to display an image (as used herein, “located on” may mean “above”). The plurality of pixels PX may be arranged in a matrix form in the first direction DR1 and the second direction DR2. The plurality of pixels PX will be described later with reference to FIG. 3.

The plurality of first side surface lines SIL1 may be located on the first surface FS, the second surface BS, at least two of the plurality of chamfered surfaces CS1 to CS8, and at least one of the plurality of side surfaces SS1 to SS4. For example, in one or more embodiments, the plurality of first side surface lines SIL1 may be located on the first surface FS, the second surface BS, the first chamfered surface CS1, the fifth chamfered surface CS5, and the first side surface SS1 to connect first pads located on the first side of the first surface FS and the first bottom surface fan-out lines BFL1 on the second surface BS to each other.

The plurality of second side surface lines SIL2 may be located on the first surface FS, the second surface BS, at least two of the plurality of chamfered surfaces CS1 to CS8, and at least one of the plurality of side surfaces SS1 to SS4. For example, in one or more embodiments, the plurality of second side surface lines SIL2 may be located on the first surface FS, the second surface BS, the third chamfered surface CS3, the seventh chamfered surface CS7, and the third side surface SS3 to connect second pads located on the third side of the first surface FS, which is a side opposite to the first side of the first surface FS, and the second bottom surface fan-out lines BFL2 on the second surface BS to each other.

In one or more embodiments, the plurality of first side surface lines SIL1 serve to connect the first pads located on the first surface FS and the first bottom surface fan-out lines BFL1 located on the second surface BS to each other, respectively. In one or more embodiments, the plurality of second side surface lines SIL2 serve to connect the second pads located on the first surface FS and the second bottom surface fan-out lines BFL2 located on the second surface BS to each other, respectively. The first pads and the second pads may correspond to front surface pads. The first pads may be connected to data lines connected to the pixels PX of the substrate SUB. Some of the second pads may be connected to a first power line located on the first surface FS of the substrate SUB, and others of the second pads may be connected to a global power line located on the first surface FS of the substrate SUB.

Each of the plurality of device identifiers DID may be an identifier, such as an identification number assigned to each of the display devices 10, and may distinguish the display devices 10 from each other. The plurality of device identifiers DID may be located on the second surface BS of the substrate SUB. The plurality of device identifiers DID may be spaced apart from the first bottom surface fan-out lines BFL1, the second bottom surface fan-out lines BFL2, the plurality of first side surface lines SIL1, and the plurality of second side surface lines SIL2 in plan view. In addition, the device identifiers DID may be spaced apart from a plurality of first circuit boards 200 and a second circuit board 400 in plan view. That is, the plurality of device identifiers DID may be in a state in which they are electrically floated.

Some of the plurality of device identifiers DID may be located adjacent to the second chamfered surface CS2, and others of the plurality of device identifiers DID may be located adjacent to the fourth chamfered surface CS4. Some of the plurality of device identifiers DID may be more adjacent to the first chamfered surface CS1 than others of the plurality of device identifiers DID are. In addition, others of the plurality of device identifiers DID may be more adjacent to the third chamfered surface CS3 than some of the plurality of device identifiers DID are.

The plurality of device identifiers DID may be back surface metal layers formed through the same process as the first bottom surface fan-out lines BFL1 and the second bottom surface fan-out lines BFL2 using the same material as the first bottom surface fan-out lines BFL1 and the second bottom surface fan-out lines BFL2. For example, the back surface metal layer may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

The plurality of first circuit boards 200 may be located on the second surface BS of the substrate SUB. The plurality of first circuit boards 200 may be connected to the first bottom surface fan-out lines BFL1 located on the second surface BS of the substrate SUB using conductive adhesive members, such as anisotropic conductive films, respectively. The plurality of first circuit boards 200 may be electrically connected to the plurality of first side surface lines SIL1 through the first bottom surface fan-out lines BFL1. Each of the plurality of first circuit boards 200 may be a flexible printed circuit board, a printed circuit board, or a flexible film.

The second circuit board 400 may be located on the second surface BS of the substrate SUB. The second circuit board 400 may be connected to the second bottom surface fan-out lines BFL2 located on the second surface BS of the substrate SUB using conductive adhesive members. The second circuit board 400 may be electrically connected to the plurality of second side surface lines SIL2 through the second bottom surface fan-out lines BFL2. The second circuit board 400 may be a flexible printed circuit board, a printed circuit board, or a flexible film.

Each of the source drivers 300 may generate data voltages, and may supply the data voltages to the data lines through the first circuit board 200, the first bottom surface fan-out lines BFL1, and the plurality of first side surface lines SIL1. Each of the source drivers 300 may be formed as an integrated circuit (IC), and may be attached onto the circuit board 200 corresponding to each of the source drivers 300. Alternatively, each of the source drivers 300 may be directly attached to the second surface BS of the substrate SUB in a chip-on-glass (COG) manner.

A power supply unit 500 may generate selected voltages, and may supply the selected voltages to selected voltage lines through the second circuit board 400, the second bottom surface fan-out lines BFL2, and the plurality of second side surface lines SIL2. For example, the power supply unit 500 may generate a first source voltage, and may supply the first source voltage to a first power line through the second circuit board 400, the second bottom surface fan-out lines BFL2, and the plurality of second side surface lines SIL2. In addition, the power supply unit 500 may generate a global source voltage GV, and may supply the global source voltage GV to a global power line through the second circuit board 400, the second bottom surface fan-out lines BFL2, and the plurality of second side surface lines SIL2. The power supply unit 500 may be formed as an integrated circuit (IC), and may be attached onto the second circuit board 400. Alternatively, the power supply unit 500 may be directly attached to the second surface BS of the substrate SUB in a chip-on-glass (COG) manner.

As illustrated in FIGS. 1 and 2, by using the plurality of first side surface lines SIL1 and the plurality of second side surface lines SIL2, it is possible to eliminate a flexible film bent along side surfaces of the substrate SUB. For this reason, a bezel-less display device may be implemented.

FIG. 3 is a layout diagram illustrating a portion of a front surface of a display panel according to one or more embodiments.

A layout of a first side of the display panel 100, a second side of the display panel 100, and a first corner of the display panel 100 where the first side and the second side meet is illustrated in FIG. 3. The first side of the display panel 100 may correspond to the left side of the display panel 100, the second side of the display panel 100 may correspond to the upper side of the display panel 100, and the first corner of the display panel 100 may be a corner where the left side and the upper side of the display panel 100 meet.

Referring to FIG. 3, the display panel 100 may include a plurality of pixels PX, a first source voltage layer VSL, and an electrostatic protection layer ASP.

The pixel PX may be defined as a minimum unit capable of expressing a white gradation. Each of the plurality of pixels PX may include L (L is an integer of 2 or more) first electrodes APD and L second electrodes CPD. For convenience of explanation, it has been mainly described in FIG. 3 that each of the plurality of pixels PX includes three first electrodes APD and three second electrodes CPD.

A pair of first electrodes APD and second electrodes CPD neighboring to each other in each of the plurality of pixels PX may be defined as one sub-pixel SP. When each of the plurality of pixels PX includes three first electrodes APD and three second electrodes CPD, each of the plurality of pixels PX may include three sub-pixels SP.

In a sub-pixel SP located at the leftmost side among a plurality of sub-pixels SP, the first electrode APD may be located at the left side, and the second electrode CPD may be located at the right side. In contrast, in each of the sub-pixels SP other than the sub-pixel SP located at the leftmost side among the plurality of sub-pixels SP, the first electrode APD may be located at the right side, and the second electrode CPD may be located at the left side.

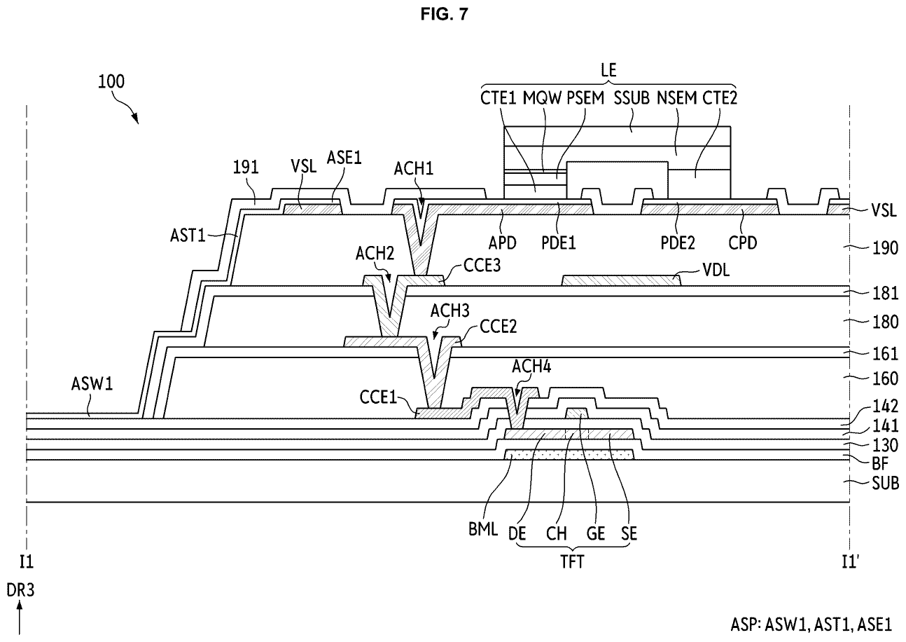

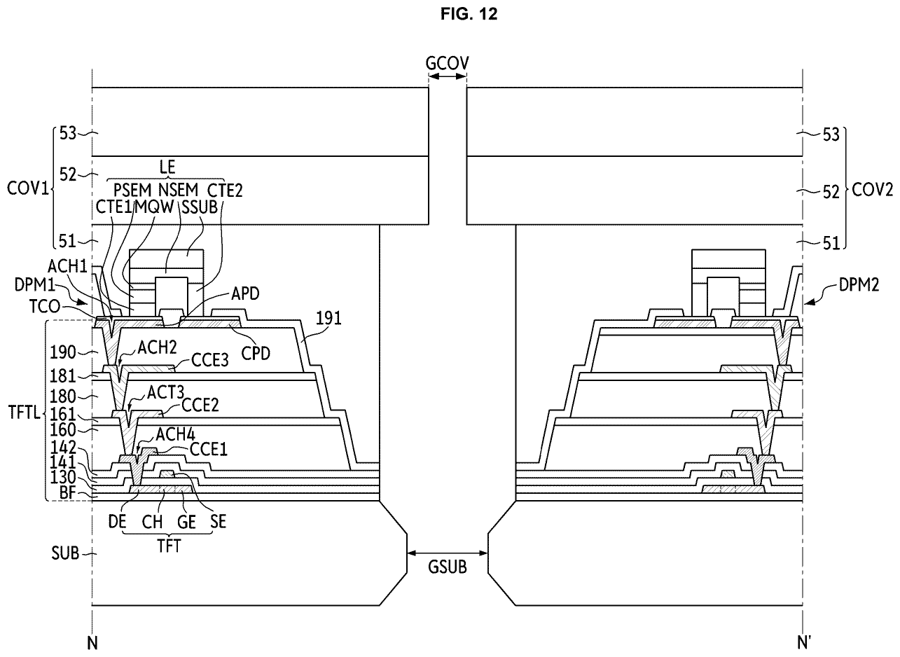

Each of a plurality of first electrodes APD may be spaced apart from a plurality of second electrodes CPD. Each of the plurality of first electrodes APD may be electrically disconnected from the plurality of second electrodes CPD. Each of the plurality of first electrodes APD may be electrically connected to one electrode of a thin film transistor TFT (see FIG. 7) through a first connection contact hole ACH1 (e.g., see FIG. 12).

Each of the plurality of second electrodes CPD may be connected to the first source voltage layer VSL. One side of each of the plurality of second electrodes CPD may be connected to the first source voltage layer VSL.

The first source voltage layer VSL may be a layer to which a first source voltage is applied or supplied. The first source voltage layer VSL may be spaced apart from the plurality of first electrodes APD. The first source voltage layer VSL may be electrically disconnected from the plurality of first electrodes APD. Because the first source voltage layer VSL is connected to the plurality of second electrodes CPD, the first source voltage of the first source voltage layer VSL may be applied to each of the plurality of second electrodes CPD. The first source voltage layer VSL may be located between sub-pixels SP neighboring to each other in each of the plurality of pixels PX.

The first source voltage layer VSL may be formed as the same conductive layer as the plurality of first electrodes APD and the plurality of second electrodes CPD. The first source voltage layer VSL may be located in most of an area where the plurality of first electrodes APD and the plurality of second electrodes CPD are not located on the front surface of the display panel 100. For this reason, an area where the first source voltage layer VSL is located may be greatly increased, and thus, a voltage drop or a voltage rising of the first source voltage applied to the first source voltage layer VSL due to resistance of the first source voltage layer VSL may be reduced.

Each of a plurality of first pad electrodes PDE1 may be spaced apart from a plurality of second pad electrodes PDE2. Each of the plurality of first pad electrodes PDE1 may be electrically disconnected from the plurality of second pad electrodes PDE2. Each of the plurality of first pad electrodes PDE1 may be located on a corresponding first electrode APD. Therefore, a first pad electrode PDE1 and a first electrode APD corresponding to the first pad electrode PDE1 may have a voltage of substantially the same potential.

Each of the plurality of second pad electrodes PDE2 may be connected to the electrostatic protection layer ASP. One side of each of the plurality of second pad electrodes PDE2 may be connected to the electrostatic protection layer ASP. Each of the plurality of second pad electrodes PDE2 may be located on a corresponding second electrode CPD. Therefore, a second pad electrode PDE2 and a second electrode CPD corresponding to the second electrode CPD may have a voltage of substantially the same potential.

The electrostatic protection layer ASP may be located at edges of the display panel 100. The electrostatic protection layer ASP may be located along the edges of the display panel 100. For example, the electrostatic protection layer ASP may be located at a left edge, an upper edge, a right edge, and a lower edge of the display panel 100. In FIG. 3, for convenience of explanation, portions of the electrostatic protection layer ASP located at the left edge and the upper edge of the display panel 100 have been illustrated. The electrostatic protection layer ASP may be formed as the same conductive layer as the plurality of first pad electrodes PDE1 and the plurality of second pad electrodes PDE2.

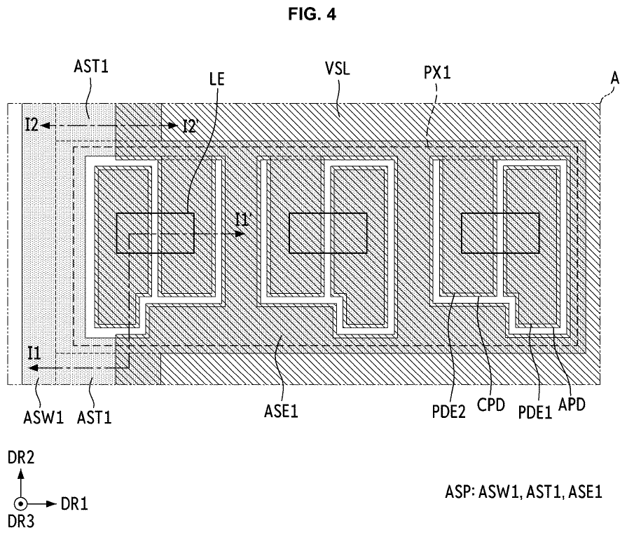

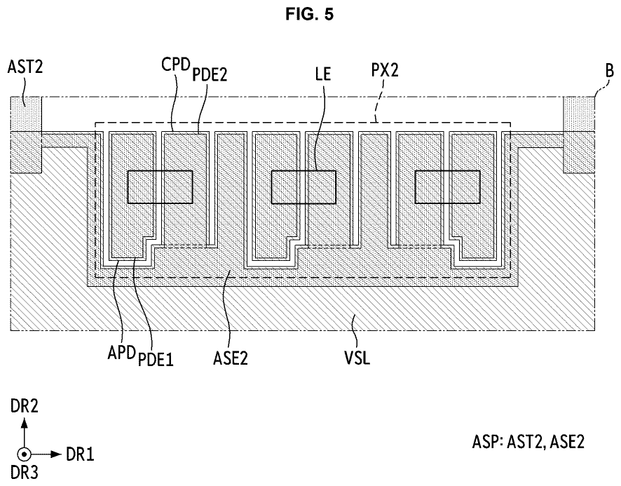

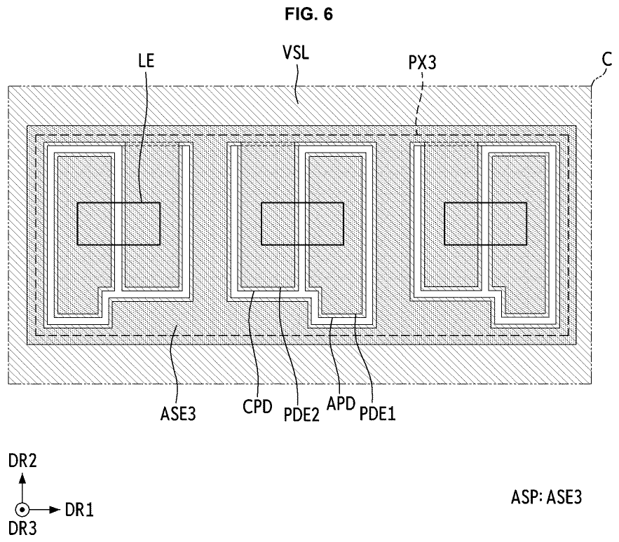

FIG. 4 is an enlarged layout diagram illustrating area A of FIG. 3 in detail. FIG. 5 is an enlarged layout diagram illustrating area B of FIG. 3 in detail. FIG. 6 is an enlarged layout diagram illustrating area C of FIG. 3 in detail.

Referring to FIGS. 3 to 6, the plurality of pixels PX may include first pixels PX1 located adjacent to a first line portion ASW1, second pixels PX2 located adjacent to a second line portion ASW2, and third pixels PXE3 excluding the first pixels PX1 and the second pixels PX2. The first pixels PX1 are located along an edge of the first side of the display panel 100 among the plurality of pixels PX. The second pixels PX2 are located along an edge of the second side of the display panel 100 among the plurality of pixels PX.

In FIG. 4, the first line portion ASW1, a first contact portion AST1, and a first electrode contact portion ASE1 of the electrostatic protection layer ASP, the first source voltage layer VSL, and the first pixels PX1 that are adjacent to the edge of the first side, that is, the left edge, of the display panel 100 are illustrated.

In FIG. 5, a second contact portion AST2 and a second electrode contact portion ASE2 of the electrostatic protection layer ASP, the first source voltage layer VSL, and the second pixels PX2 that are adjacent to the edge of the second side, that is, the upper edge, of the display panel 100 are illustrated.

In FIG. 6, a third electrode contact portion ASE3 of the electrostatic protection layer ASP and the third pixels PX3 that are located in an area other than the edges of the display panel 100 are illustrated.

The electrostatic protection layer ASP may include the first line portion ASW1, the second line portion ASW2, the first contact portion AST1, the second contact portion AST2, the first electrode contact portion ASE1, the second electrode contact portion ASE2, and the third electrode contact portion ASE3, as illustrated in FIGS. 3 to 6.

The first line portion ASW1 may be located at the edge of the first side, for example, the left edge, of the display panel 100. The first line portion ASW1 may be located along the edge of the first side of the display panel 100, and may extend in the second direction DR2.

The second line portion ASW2 may be located at the edge of the second side, for example, the upper edge, of the display panel 100. The second line portion ASW2 may be located along the edge of the second side of the display panel 100, and may extend in the first direction DR1.

The first contact portion AST1 may connect the first line portion ASW1 and the first source voltage layer VSL to each other. The first contact portion AST1 may protrude and extend from the first line portion ASW1 in the first direction DR1. The first contact portion AST1 may be in contact with the first source voltage layer VSL.

The second contact portion AST2 may connect the second line portion ASW2 and the first source voltage layer VSL to each other. The second contact portion AST2 may protrude and extend from the second line portion ASW2 in the second direction DR2. The second contact portion AST2 may be in contact with the first source voltage layer VSL.

Because a distance DE1 between the first source voltage layer VSL and the edge of the first side of the display panel 100 is less than a distance DE2 between the first source voltage layer VSL and the edge of the second side of the display panel 100, a distance DS1 between the first line portion ASW1 and the first source voltage layer VSL is less than a distance DS2 between the second line portion ASW2 and the first source voltage layer VSL. Therefore, a length DT1 of the first contact portion AST1 in the first direction DR1 may be less than a length DT2 of the second contact portion AST2 in the second direction DR2.

The first electrode contact portion ASE1 may extend from the first contact portion AST1. The first electrode contact portion ASE1 may connect the first source voltage layer VSL and the second pad electrodes PDE2 of each of the first pixels PX1 to each other. The first electrode contact portion ASE1 may be connected to one side of each of the second pad electrodes PDE2 of each of the first pixels PX1.

The first electrode contact portion ASE1 may be spaced apart from the first pad electrodes PDE1 of each of the first pixels PX1. The first electrode contact portion ASE1 may be electrically disconnected from the first pad electrodes PDE1 of each of the first pixels PX1.

The first electrode contact portion ASE1 may surround at least one of the first pad electrodes PDE1 of each of the first pixels PX1. For example, a first pad electrode PDE1 located adjacent to the first line portion ASW1 among the first pad electrodes PDE1 of each of the first pixels PX1 may be surrounded by the first line portion ASW1 and the first electrode contact portion ASE1. First pad electrodes PDE1 other than the first pad electrode PDE1 located adjacent to the first line portion ASW1 of the first pixels PX1 may be surrounded by the first electrode contact portion ASE1.

The second electrode contact portion ASE2 may extend from the second contact portion AST2. The second electrode contact portion ASE2 may connect the first source voltage layer VSL and the second pad electrodes PDE2 of each of the second pixels PX2 to each other. The second electrode contact portion ASE2 may be connected to a first side of each of the second pad electrodes PDE2 of each of the second pixels PX2. A second side of each of the second pad electrodes PDE2 may face the second line portion ASW2.

The second electrode contact portion ASE2 may be spaced apart from the first pad electrodes PDE1 of each of the second pixels PX2. The second electrode contact portion ASE2 may be electrically disconnected from the first pad electrodes PDE1 of each of the second pixels PX2.

The second electrode contact portion ASE2 may be located on at least one side of each of the first pad electrodes PDE1 of each of the second pixels PX2. For example, the second electrode contact portion ASE2 may be located on a first side of a first pad electrode PDE1 located at the center among the first pad electrodes PDE1 of each of the second pixels PX2. The second electrode contact portion ASE2 may be located on at least two sides of each of the first pad electrodes PDE1 located at an edge among the first pad electrodes PDE1 of each of the second pixels PX2.

In addition, the second electrode contact portion ASE2 may expose a second side of at least one of the first pad electrodes PDE1 of each of the second pixels PX2. The second side of the first pad electrode PDE1 may be a side opposite to the first side. The second side of the first pad electrode PDE1 may face the second line portion ASW2.

The third electrode contact portion ASE3 may connect the first source voltage layer VSL and the second pad electrodes PDE2 of each of the third pixels PX3 to each other. The third electrode contact portion ASE3 may be connected to a first side of each of the second pad electrodes PDE2 of each of the third pixels PX3.

The third electrode contact portion ASE3 may be spaced apart from the first pad electrodes PDE1 of each of the third pixels PX3. The third electrode contact portion ASE3 may be electrically disconnected from the first pad electrodes PDE1 of each of the third pixels PX3.

The third electrode contact portion ASE3 may surround at least one of the first pad electrodes PDE1 of each of the third pixels PX3. For example, each of the first pad electrodes PDE1 of each of the third pixels PX3 may be surrounded by the third electrode contact portion ASE3.

As illustrated in FIGS. 3 to 6, static electricity flowing into the first line portion ASW1 and the second line portion ASW2 of the edges of the display panel 100 may be discharged to the first source voltage layer VSL through the first contact portion AST1 and the second contact portion AST2. In addition, static electricity flowing into the first pixels PX1 and the second pixels PX2 adjacent to the edges of the display panel 100 may be discharged to the first source voltage layer VSL through the first electrode contact portion ASE1 and the second electrode contact portion ASE2. Furthermore, static electricity flowing into the third pixels PX3 located at a central portion of the display panel 100, rather than at the edges of the display panel 100, may also be discharged to the first source voltage layer VSL through the third electrode contact portion ASE3. Therefore, static electricity flowing into areas adjacent to light-emitting elements LE on the front surface of the display panel 100 may be stably discharged to the first source voltage layer VSL.

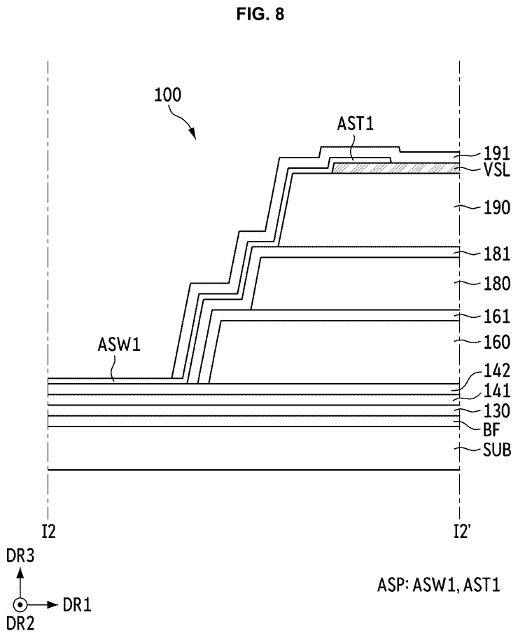

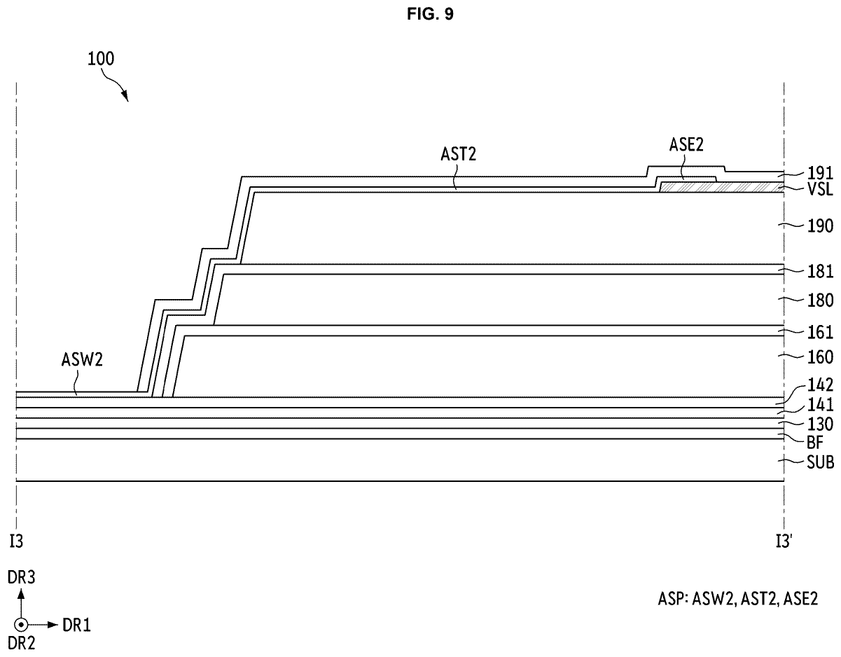

FIG. 7 is a cross-sectional view illustrating an example of a cross section of the display panel taken along the line I1-I1′ of FIG. 4. FIG. 8 is a cross-sectional view illustrating an example of a cross section of the display panel taken along the line I2-I2′ of FIG. 4. FIG. 9 is a cross-sectional view illustrating an example of a cross section of the display panel taken along the line I3-I3′ of FIG. 3.

Referring to FIGS. 7 to 9, the display panel 100 may include a substrate SUB, a thin film transistor layer, and a light-emitting element layer.

The substrate SUB may be made of an insulating material, such as glass or a polymer resin. For example, when the substrate SUB is made of the polymer resin, the substrate SUB may include polyimide. The substrate SUB may be a flexible substrate that may be bent, folded, and rolled.

The thin film transistor layer may be located on the substrate SUB. The thin film transistor layer includes a plurality of thin film transistors TFT, a lower light-blocking pattern BML, a buffer film BF, and a plurality of insulating films 130, 141, 142, 160, 161, 180, 181, 190, and 191.

The lower light-blocking pattern BML may be located on the substrate SUB. The lower light-blocking pattern BML may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof. The lower light-blocking pattern BML may be formed to have a thickness of approximately 3,000 Å or more to serve as a light-blocking structure.

The buffer film BF may be located on the lower light-blocking pattern BML. The buffer film BF may include a plurality of inorganic films that are alternately stacked. For example, the buffer film BF may be formed as multiple films in which one or more inorganic films of a silicon nitride layer, a silicon oxynitride layer, a silicon oxide layer, a titanium oxide layer, and an aluminum oxide layer are alternately stacked.

The plurality of thin film transistors TFT may be located on the buffer film BF. In FIG. 7, for convenience of explanation, a thin film transistor TFT connected to the first electrode APD has been illustrated.

An active layer of the thin film transistor TFT may be located on the buffer film BF. The active layer of the thin film transistor TFT includes a channel CH, a source electrode SE, and a drain electrode DE.

A gate-insulating film 130 may be located on the active layer of the thin film transistor TFT. The gate-insulating film 130 may be formed as an inorganic insulating film, such as a silicon nitride (SiNₓ) film, a silicon oxide (SiOₓ) film, a silicon oxynitride (SiON) film, a titanium oxide (TiOₓ) film, or an aluminum oxide (AlOₓ) film.

A first gate metal layer may be located on the gate-insulating film 130. The first gate metal layer includes a gate electrode GE of the thin film transistor TFT. The gate electrode GE of the thin film transistor TFT may overlap the channel CH in a third direction DR3, which is a thickness direction of the substrate SUB. The first gate metal layer may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

A first interlayer insulating film 141 may be located on the first gate metal layer. The first interlayer insulating film 141 may be formed as an inorganic insulating film, such as a silicon nitride (SiNₓ) film, a silicon oxide (SiOₓ) film, a silicon oxynitride (SiON) film, a titanium oxide (TiOₓ) film, or an aluminum oxide (AlOₓ) film.

A second gate metal layer may be located on the first interlayer insulating film 141. In one or more embodiments, the second gate metal layer may include a capacitor electrode overlapping the gate electrode GE of the thin film transistor TFT. The second gate metal layer may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

A second interlayer insulating film 142 may be located on the second gate metal layer. The second interlayer insulating film 142 may be formed as an inorganic insulating film, such as a silicon nitride (SiNₓ) film, a silicon oxide (SiOₓ) film, a silicon oxynitride (SiON) film, a titanium oxide (TiOₓ) film, or an aluminum oxide (AlOₓ) film.

A first source metal layer may be located on the second interlayer insulating film 142. The first source metal layer includes a first connection electrode CCE1. The first connection electrode CCE1 may be connected to the drain electrode DE of the thin film transistor TFT through a fourth connection contact hole ACH4 penetrating through the gate-insulating film 130, the first interlayer insulating film 141, and the second interlayer insulating film 142. The first source metal layer may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

A first planarization film 160 may be located on the first source metal layer. The first planarization film 160 may be formed as an organic insulating film made of an acrylic resin, an epoxy resin, a phenolic resin, a polyamide resin, a polyimide resin, or the like.

A first inorganic insulating film 161 may be located on the first planarization film 160. The first inorganic insulating film 161 may be formed as a silicon nitride (SiNₓ) film, a silicon oxide (SiOₓ) film, a silicon oxynitride (SiON) film, a titanium oxide (TiOₓ) film, or an aluminum oxide (AlOₓ) film.

A second source metal layer may be located on the first inorganic insulating film 161. The second source metal layer includes a second connection electrode CCE2. The second connection electrode CCE2 may be connected to the first connection electrode CCE1 through a third connection contact hole ACH3 penetrating through the first planarization film 160 and the first inorganic insulating film 161. The second source metal layer may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

A second planarization film 180 may be located on the second source metal layer. The second planarization film 180 may be formed as an organic insulating film made of an acrylic resin, an epoxy resin, a phenolic resin, a polyamide resin, a polyimide resin, or the like.

A second inorganic insulating film 181 may be located on the second planarization film 180. The second inorganic insulating film 181 may be formed as a silicon nitride (SiNₓ) film, a silicon oxide (SiOₓ) film, a silicon oxynitride (SiON) film, a titanium oxide (TiOₓ) film, or an aluminum oxide (AlOₓ) film.

A third source metal layer may be located on the second inorganic insulating film 181. The third source metal layer includes the third connection electrode CCE3. The third connection electrode CCE3 may be connected to the second connection electrode CCE2 through a second connection contact hole ACH2 penetrating through the second planarization film 180 and the second inorganic insulating film 181. The third source metal layer may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

A third planarization film 190 may be located on the third source metal layer. The third planarization film 190 may be formed as an organic insulating film made of an acrylic resin, an epoxy resin, a phenolic resin, a polyamide resin, a polyimide resin, or the like.

A fourth source metal layer may be located on the third planarization film 190. The fourth source metal layer includes the first electrode APD, the second electrode CPD, and the first source voltage layer VSL. The first electrode APD may be connected to the third connection electrode CCE3 through the first connection contact hole ACH1 penetrating through the third planarization film 190.

The fourth source metal layer may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

The first pad electrode PDE1 may be located on the first electrode APD, and the second pad electrode PDE2 may be located on the second electrode CPD. A thickness of the first pad electrode PDE1 may be less than a thickness of the first electrode APD. A thickness of the second pad electrode PDE2 may be less than a thickness of the second electrode CPD. The first pad electrode PDE1 may be electrically connected to a first electrode CTE1 of a light-emitting element LE. The second pad electrode PDE2 may be electrically connected to a second electrode CTE2 of the light-emitting element LE.

The first electrode contact portion ASE1 of the electrostatic protection layer ASP may be located on the first source voltage layer VSL. The second electrode contact portion ASE2 of the electrostatic protection layer ASP may also be located on the first source voltage layer VSL.

A portion of the first contact portion AST1 of the electrostatic protection layer ASP may be located on the first source voltage layer VSL, and the other portion of the first contact portion AST1 of the electrostatic protection layer ASP may not be located on the first source voltage layer VSL. A portion of the first contact portion AST1 of the electrostatic protection layer ASP may be connected to the first electrode contact portion ASE1. The other portion of the first contact portion AST1 of the electrostatic protection layer ASP may be located on at least one of the first planarization film, the second planarization film, or the third planarization film.

A portion of the second contact portion AST2 of the electrostatic protection layer ASP may be located on the first source voltage layer VSL, and the other portion of the second contact portion AST2 of the electrostatic protection layer ASP may not be located on the first source voltage layer VSL. A portion of the second contact portion AST2 of the electrostatic protection layer ASP may be connected to the second electrode contact portion ASE2. The other portion of the second contact portion AST2 of the electrostatic protection layer ASP may be located on at least one of the first planarization film, the second planarization film, or the third planarization film.

The first line portion ASW1 of the electrostatic protection layer ASP may be located on an edge of the substrate SUB. The first line portion ASW1 of the electrostatic protection layer ASP may be connected to the first contact portion AST1. The first line portion ASW1 of the electrostatic protection layer ASP may be located on the second interlayer insulating film 142. The first line portion ASW1 of the electrostatic protection layer ASP may be exposed without being covered by another component.

The second line portion ASW2 of the electrostatic protection layer ASP may be located on an edge of the substrate SUB. The second line portion ASW2 of the electrostatic protection layer ASP may be connected to the second contact portion AST2. The second line portion ASW2 of the electrostatic protection layer ASP may be located on the second interlayer insulating film 142. The second line portion ASW2 of the electrostatic protection layer ASP may be exposed without being covered by another component.

The electrostatic protection layer ASP may be made of substantially the same material as the first pad electrode PDE1 and the second pad electrode PDE2. For example, each of the first pad electrode PDE1, the second pad electrode PDE2, and the electrostatic protection layer ASP may be made of a transparent conductive oxide (TCO), such as indium tin oxide (ITO) and indium zinc oxide (IZO), but one or more embodiments of the present disclosure is not limited thereto. A thickness of the electrostatic protection layer ASP may be less than a thickness of the first source voltage layer VSL.

A third inorganic insulating film 191 may be located on the first pad electrode PDE1, the second pad electrode PDE2, and the electrostatic protection layer ASP. The third inorganic insulating film 191 may cover an edge of the first electrode APD and an edge of the second electrode CPD. The third inorganic insulating film 191 may be located on the first contact portion AST1, the second contact portion AST2, the first electrode contact portion ASE1, and the second electrode contact portion ASE2 of the electrostatic protection layer ASP. The third inorganic insulating film 191 may not be located on the first line portion ASW1 and the second line portion ASW2 of the electrostatic protection layer ASP. The third inorganic insulating film 191 may be formed as a silicon nitride (SiNₓ) film, a silicon oxide (SiOₓ) film, a silicon oxynitride (SiON) film, a titanium oxide (TiOₓ) film, or an aluminum oxide (AlOₓ) film.

The light-emitting element layer may be located on the first pad electrode PDE1 and the second pad electrode PDE2. The light-emitting element layer may include light-emitting elements LE.

It has been illustrated that the light-emitting element LE is a flip chip-type micro light-emitting diode (LED) whose first electrode CTE1 faces the first electrode APD and whose second electrode CTE2 faces the second electrode CPD. The light-emitting element LE may be made of an inorganic material, such as gallium nitride (GaN). Each of lengths of the light-emitting element LE in the first direction DR1, the second direction DR2, and the third direction DR3 may be several to several hundred micrometers. For example, each of lengths of the light-emitting element LE in the first direction DR1, the second direction DR2, and the third direction DR3 may be approximately 100 μm or less.

The light-emitting elements LE may be grown and formed on a semiconductor substrate, such as a silicon wafer. Each of the light-emitting elements LE may be directly transferred from the silicon wafer onto the first pad electrode PDE1 and the second pad electrode PDE2 of the substrate SUB. Alternatively, each of the light-emitting elements LE may be transferred onto the first pad electrode PDE1 and the second pad electrode PDE2 of the substrate SUB through an electrostatic method using an electrostatic head or a stamp method using an elastic polymer material, such as polydimethylsiloxane (PDMS) or silicon as a material of a transfer substrate.

The light-emitting element LE may be a light-emitting structure including a base substrate SSUB, an n-type semiconductor NSEM, an active layer MQW, a p-type semiconductor PSEM, the first electrode CTE1, and the second electrode CTE2.

The base substrate SSUB may be a sapphire substrate, but one or more embodiments of the present disclosure is not limited thereto.

The n-type semiconductor NSEM may be located on (e.g., below) one surface of the base substrate SSUB. For example, the n-type semiconductor NSEM may be located on a lower surface of the base substrate SSUB. The n-type semiconductor NSEM may be made of GaN doped with an n-type dopant, such as Si, Ge, or Sn.

The active layer MQW may be located on a portion of one surface of the n-type semiconductor NSEM. The active layer MQW may include a material having a single or multiple quantum well structure. When the active layer MQW includes the material having the multiple quantum well structure, the active layer MQW may have a structure in which a plurality of well layers and barrier layers are alternately stacked. In this case, the well layer may be made of InGaN, and the barrier layer may be made of GaN or AlGaN, but the present disclosure is not limited thereto. Alternatively, the active layer MQW may have a structure in which semiconductor materials having great band gap energy and semiconductor materials having small band gap energy are alternately stacked, and may include other Group III to Group V semiconductor materials depending on a wavelength band of emitted light.

The p-type semiconductor PSEM may be located on one surface of the active layer MQW. The p-type semiconductor PSEM may be made of GaN doped with a p-type dopant, such as Mg, Zn, Ca, Se, or Ba.

The first electrode CTE1 may be located on the p-type semiconductor PSEM, and the second electrode CTE2 may be located on another portion of one surface of the n-type semiconductor NSEM. Another portion of one surface of the n-type semiconductor NSEM on which the second electrode CTE2 is located may be spaced apart from a portion of one surface of the n-type semiconductor NSEM on which the active layer MQW is located.

The first electrode CTE1 may be adhered to the first pad electrode PDE1 through a conductive adhesive member, such as an anisotropic conductive film (ACF) or an anisotropic conductive paste (ACP). Alternatively, the first electrode CTE1 may be adhered to the first pad electrode PDE1 through a soldering process.

The second electrode CTE2 may be adhered to the second pad electrode PDE2 through a conductive adhesive member, such as an ACF or an ACP. Alternatively, the second electrode CTE2 may be adhered to the second pad electrode PDE2 through a soldering process.

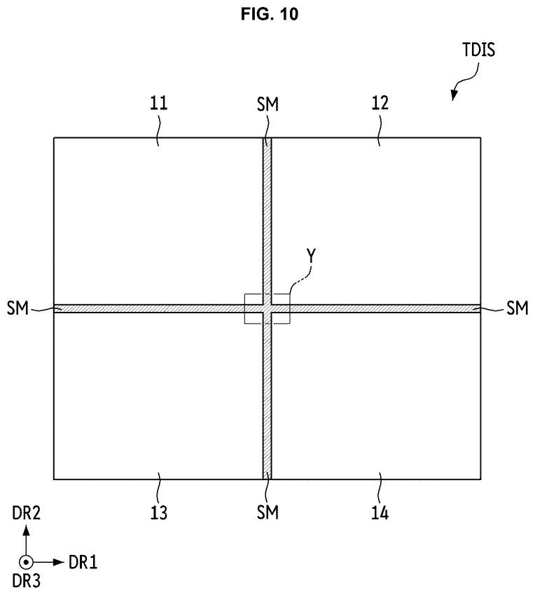

FIG. 10 is a perspective view illustrating a tiled display device including a plurality of display devices according to one or more embodiments.

Referring to FIG. 10, a tiled display device TDIS may include a plurality of display devices 11, 12, 13, and 14 and a seam portion SM. The plurality of display devices 11, 12, 13, and 14 may be arranged in a matrix form in M (M is a positive integer) rows and N (N is a positive integer) columns. For example, the tiled display device TDIS may include a first display device 11, a second display device 12, a third display device 13, and a fourth display device 14.

The first display device 11 and the second display device 12 may neighbor each other in the first direction DR1. The first display device 11 and the third display device 13 may neighbor each other in the second direction DR2. The third display device 13 and the fourth display device 14 may neighbor each other in the first direction DR1. The second display device 12 and the fourth display device 14 may neighbor each other in the second direction DR2.

However, the number and an arrangement of display devices 11, 12, 13, and 14 in the tiled display device TDIS are not limited to those illustrated in FIG. 10. The number and an arrangement of display devices 11, 12, 13, and 14 in the tiled display device TDIS may be determined according to sizes of each of the display device 10 and the tiled display device TDIS and a shape of the tiled display device TDIS.

The plurality of display devices 11, 12, 13, and 14 may have the same size, but one or more embodiments of the present disclosure is not limited thereto. For example, the plurality of display devices 11, 12, 13, and 14 may have different sizes.

Each of the plurality of display devices 11, 12, 13, and 14 may have a rectangular shape having long sides and short sides. The plurality of display devices 11, 12, 13, and 14 may be located with long sides or short sides connected to each other. Some or all of the plurality of display devices 11, 12, 13, and 14 may be located at edges of the tiled display device TDIS, and may form one side of the tiled display device TDIS. At least one of the plurality of display devices 11, 12, 13, or 14 may be located at at least one corner of the tiled display device TDIS, and may form two adjacent sides of the tiled display device TDIS. At least one of the plurality of display devices 11, 12, 13, or 14 may be surrounded by the other display devices.

Each of the plurality of display devices 11, 12, 13, and 14 may be substantially the same as the display device 10 described with reference to FIG. 1. Therefore, a description of each of the plurality of display devices 11, 12, 13, and 14 is omitted.

The seam portion SM may include a coupling member or an adhesive member. In this case, the plurality of display devices 11, 12, 13, and 14 may be connected to each other through the coupling member or the adhesive member of the seam portion SM. The seam portion SM may be located between the first display device 11 and the second display device 12, between the first display device 11 and the third display device 13, between the second display device 12 and the fourth display device 14, and between the third display device 13 and the fourth display device 14.

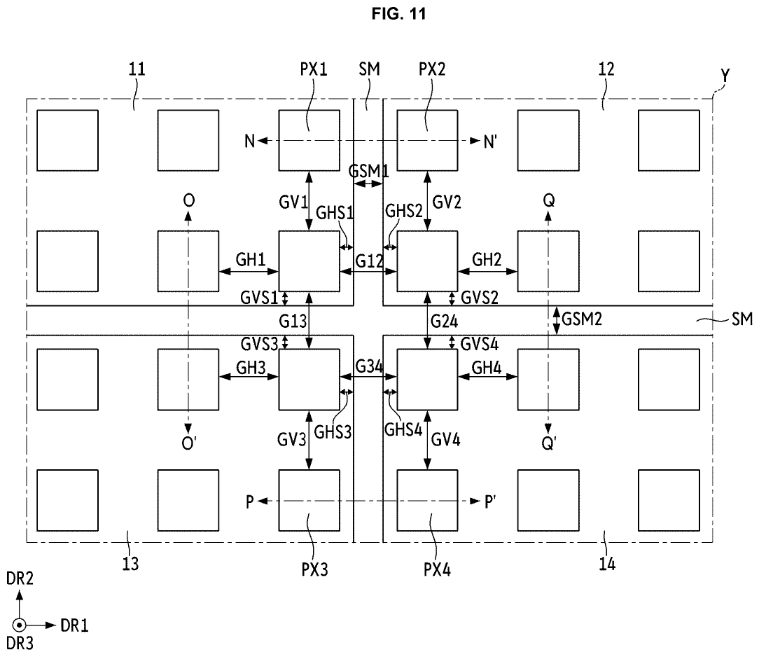

FIG. 11 is an enlarged layout diagram illustrating area Y of FIG. 10 in detail.

Referring to FIG. 11, the seam portion SM may have a cross shape or a plus sign (+) shape in plan view in a central area of the tiled display device TDIS where the first display device 11, the second display device 12, the third display device 13, and the fourth display device 14 are adjacent to each other. The seam portion SM may be located between the first display device 11 and the second display device 12, between the first display device 11 and the third display device 13, between the second display device 12 and the fourth display device 14, and between the third display device 13 and the fourth display device 14.

The first display device 11 may include first pixels PX1 arranged in a matrix form in the first direction DR1 and the second direction DR2 to display an image. The second display device 12 may include second pixels PX2 arranged in a matrix form in the first direction DR1 and the second direction DR2 to display an image. The third display device 13 may include third pixels PX3 arranged in a matrix form in the first direction DR1 and the second direction DR2 to display an image. The fourth display device 14 may include fourth pixels PX4 arranged in a matrix form in the first direction DR1 and the second direction DR2 to display an image.

A minimum distance between the first pixels PX1 neighboring to each other in the first direction DR1 may be defined as a first horizontal spaced distance GH1, and a minimum distance between the second pixels PX2 neighboring to each other in the first direction DR1 may be defined as a second horizontal spaced distance GH2. The first horizontal spaced distance GH1 and the second horizontal spaced distance GH2 may be substantially the same as each other.

The seam portion SM may be located between the first pixel PX1 and the second pixel PX2 neighboring to each other in the first direction DR1. A minimum distance G12 between the first pixel PX1 and the second pixel PX2 neighboring to each other in the first direction DR1 may be the sum of a minimum distance GHS1 between the first pixel PX1 and the seam portion SM in the first direction DR1, a minimum distance GHS2 between the second pixel PX2 and the seam portion SM in the first direction DR1, and a width GSM1 of the seam portion SM in the first direction DR1.

The minimum distance G12 between the first pixel PX1 and the second pixel PX2 neighboring to each other in the first direction DR1, the first horizontal spaced distance GH1, and the second horizontal spaced distance GH2 may be substantially the same as each other. To this end, the minimum distance GHS1 between the first pixel PX1 and the seam portion SM in the first direction DR1 may be less than the first horizontal spaced distance GH1, and the minimum distance GHS2 between the second pixel PX2 and the seam portion SM in the first direction DR1 may be less than the second horizontal spaced distance GH2. In addition, the width GSM1 of the seam portion SM in the first direction DR1 may be less than the first horizontal spaced distance GH1 or the second horizontal spaced distance GH2.

A minimum distance between the third pixels PX3 neighboring to each other in the first direction DR1 may be defined as a third horizontal spaced distance GH3, and a minimum distance between the fourth pixels PX4 neighboring to each other in the first direction DR1 may be defined as a fourth horizontal spaced distance GH4. The third horizontal spaced distance GH3 and the fourth horizontal spaced distance GH4 may be substantially the same as each other.

The seam portion SM may be located between the third pixel PX3 and the fourth pixel PX4 neighboring to each other in the first direction DR1. A minimum distance G34 between the third pixel PX3 and the fourth pixel PX4 neighboring to each other in the first direction DR1 may be the sum of a minimum distance GHS3 between the third pixel PX3 and the seam portion SM in the first direction DR1, a minimum distance GHS4 between the fourth pixel PX4 and the seam portion SM in the first direction DR1, and the width GSM1 of the seam portion SM in the first direction DR1.

The minimum distance G34 between the third pixel PX3 and the fourth pixel PX4 neighboring to each other in the first direction DR1, the third horizontal spaced distance GH3, and the fourth horizontal spaced distance GH4 may be substantially the same as each other. To this end, the minimum distance GHS3 between the third pixel PX3 and the seam portion SM in the first direction DR1 may be less than the third horizontal spaced distance GH3, and the minimum distance GHS4 between the fourth pixel PX4 and the seam portion SM in the first direction DR1 may be less than the fourth horizontal spaced distance GH4. In addition, the width GSM1 of the seam portion SM in the first direction DR1 may be less than the third horizontal spaced distance GH3 or the fourth horizontal spaced distance GH4.

A minimum distance between the first pixels PX1 neighboring to each other in the second direction DR2 may be defined as a first vertical spaced distance GV1, and a minimum distance between the third pixels PX3 neighboring to each other in the second direction DR2 may be defined as a third vertical spaced distance GV3. The first vertical spaced distance GV1 and the third vertical spaced distance GV3 may be substantially the same as each other.

The seam portion SM may be located between the first pixel PX1 and the third pixel PX3 neighboring to each other in the second direction DR2. A minimum distance G13 between the first pixel PX1 and the third pixel PX3 neighboring to each other in the second direction DR2 may be the sum of a minimum distance GVS1 between the first pixel PX1 and the seam portion SM in the second direction DR2, a minimum distance GVS3 between the third pixel PX3 and the seam portion SM in the second direction DR2, and a width GSM2 of the seam portion SM in the second direction DR2.

The minimum distance G13 between the first pixel PX1 and the third pixel PX3 neighboring to each other in the second direction DR2, the first vertical spaced distance GV1, and the third vertical spaced distance GV3 may be substantially the same as each other. To this end, the minimum distance GVS1 between the first pixel PX1 and the seam portion SM in the second direction DR2 may be less than the first vertical spaced distance GV1, and the minimum distance GVS3 between the third pixel PX3 and the seam portion SM in the second direction DR2 may be less than the third vertical spaced distance GV3. In addition, the width GSM2 of the seam portion SM in the second direction DR2 may be less than the first vertical spaced distance GV1 or the third vertical spaced distance GV3.

A minimum distance between the second pixels PX2 neighboring to each other in the second direction DR2 may be defined as a second vertical spaced distance GV2, and a minimum distance between the fourth pixels PX4 neighboring to each other in the second direction DR2 may be defined as a fourth vertical spaced distance GV4. The second vertical spaced distance GV2 and the fourth vertical spaced distance GV4 may be substantially the same as each other.

The seam portion SM may be located between the second pixel PX2 and the fourth pixel PX4 neighboring to each other in the second direction DR2. A minimum distance G24 between the second pixel PX2 and the fourth pixel PX4 neighboring to each other in the second direction DR2 may be the sum of a minimum distance GVS2 between the second pixel PX2 and the seam portion SM in the second direction DR2, a minimum distance GVS4 between the fourth pixel PX4 and the seam portion SM in the second direction DR2, and the width GSM2 of the seam portion SM in the second direction DR2.

The minimum distance G24 between the second pixel PX2 and the fourth pixel PX4 neighboring to each other in the second direction DR2, the second vertical spaced distance GV2, and the fourth vertical spaced distance GV4 may be substantially the same as each other. To this end, the minimum distance GVS2 between the second pixel PX2 and the seam portion SM in the second direction DR2 may be less than the second vertical spaced distance GV2, and the minimum distance GVS4 between the fourth pixel PX4 and the seam portion SM in the second direction DR2 may be less than the fourth vertical spaced distance GV4. In addition, the width GSM2 of the seam portion SM in the second direction DR2 may be less than the second vertical spaced distance GV2 or the fourth vertical spaced distance GV4.

As illustrated in FIG. 11, to reduce or prevent visibility of the seam portion SM between images displayed by the plurality of display devices 11, 12, 13, and 14, a minimum distance between pixels of the display devices neighboring to each other may be substantially the same as a minimum distance between pixels of each of the display devices.

FIG. 12 is a cross-sectional view illustrating an example of the tiled display device taken along the line N-N′ of FIG. 11.

Referring to FIG. 12, the first display device 11 includes a first display module DPM1 and a first front cover COV1. The second display device 12 includes a second display module DPM2 and a second front cover COV2.

Each of the first display module DPM1 and the second display module DPM2 includes a substrate SUB, a thin film transistor TFT, and a light-emitting element LE. The substrate SUB, the thin film transistor TFT, and the light-emitting element LE illustrated in FIG. 12 are substantially the same as the substrate SUB, the thin film transistor TFT, and the light-emitting element LE described with reference to FIG. 7, and a description thereof is thus omitted.

A distance GSUB between a substrate SUB of the first display device 11 and a substrate SUB of the second display device 12 may be greater than a distance GCOV between the first front cover COV1 and the second front cover COV2.

Each of the first front cover COV1 and the second front cover COV2 may include an adhesive member 51, a light-transmissivity-adjusting layer 52 located on the adhesive member 51, and an anti-glare layer 53 located on the light-transmissivity-adjusting layer 52.

The adhesive member 51 of the first front cover COV1 serves to adhere the first display module DPM1 and the first front cover COV1 to each other. The adhesive member 51 of the second front cover COV2 serves to adhere the second display module DPM2 and the second front cover COV2 to each other. The adhesive member 51 may be a transparent adhesive member capable of transmitting light. For example, the adhesive member 51 may be an optically clear adhesive film or an optically clear resin.

The anti-glare layer 53 may be designed to diffusely reflect external light to reduce or prevent deterioration of visibility of an image occurring because the external light is reflected as it is. Accordingly, a contrast ratio of images displayed by the first display device 11 and the second display device 12 may be increased due to the anti-glare layer 53.

The light-transmissivity-adjusting layer 52 may be designed to reduce transmissivity of external light or light reflected from the first display module DPM1 and the second display module DPM2. For this reason, visibility from the outside of the distance GSUB between the substrate SUB of the first display module DPM1 and the substrate SUB of the second display module DPM2 may be reduced or prevented.

The anti-glare layer 53 may be implemented as a polarizing plate, and the light-transmissivity-adjusting layer 52 may be implemented as a phase delay layer, but one or more embodiments of the present disclosure is not limited thereto.

An example of the tiled display device taken along the line O-O′, the line P-P′, and the line Q-Q′ of FIG. 11 is substantially the same as an example of the tiled display device taken along the line N-N′ described with reference to FIG. 12, and a repeated description thereof is thus omitted.

It should be understood, however, that the aspects of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
first electrodes above the substrate;
second electrodes above the substrate;
first pad electrodes respectively above the first electrodes;
second pad electrodes respectively above the second electrodes;
light-emitting elements respectively above the first pad electrodes and the second pad electrodes;
a first source voltage layer connected to the second electrodes; and
an electrostatic protection layer at an edge of at least one side of the substrate, and connected to the second pad electrodes and to the first source voltage layer.

2. The display device of claim 1, wherein the first pad electrodes, the second pad electrodes, and the electrostatic protection layer comprise a transparent conductive oxide.

3. The display device of claim 1, wherein the first electrodes, the second electrodes, and the first source voltage layer comprise an opaque metal material.

4. The display device of claim 1, wherein the electrostatic protection layer comprises:
a first line portion at an edge of a first side of the substrate, and extending in a second direction; and
a first contact portion extending from the first line portion in a first direction crossing the second direction, and contacting the first source voltage layer.

5. The display device of claim 4, wherein the electrostatic protection layer further comprises:
a second line portion at an edge of a second side of the substrate that is adjacent to the first side, and extending in the first direction; and
a second contact portion extending from the second line portion in the second direction, and contacting the first source voltage layer.

6. The display device of claim 5, wherein a length of the first contact portion in the first direction is less than a length of the second contact portion in the second direction.

7. The display device of claim 5, further comprising pixels comprising L first electrodes of the first electrodes and L second electrodes of the second electrodes are defined above the substrate, L being an integer of 2 or more.

8. The display device of claim 7, wherein the electrostatic protection layer further comprises a first electrode contact portion extending from the first line portion, and contacting the second electrodes of a first one of the pixels adjacent to the first line portion.

9. The display device of claim 8, wherein the first electrode contact portion is connected to one side of the second electrodes of the first one of the pixels.

10. The display device of claim 8, wherein the first electrode contact portion surrounds at least one of the first electrodes of the first one of the pixels.

11. The display device of claim 8, wherein one of the first electrodes adjacent to the first line portion of the first one of the pixels is surrounded by the first line portion and the first electrode contact portion.

12. The display device of claim 8, wherein the first electrodes, other than one of the first electrodes adjacent to the first line portion of the first one of the pixels, are surrounded by the first electrode contact portion.

13. The display device of claim 7, wherein the electrostatic protection layer further comprises a second electrode contact portion extending from the second contact portion, and contacting the second electrodes of a second one of the pixels that is adjacent to the second line portion.

14. The display device of claim 13, wherein the second electrode contact portion is connected to a first side of the second electrodes of the second one of the pixels, and a second side of the second electrodes of the second one of the pixels faces the second line portion.

15. The display device of claim 13, wherein one side of the first electrodes of the second one of the pixels is exposed without being surrounded by the second electrode contact portion.

16. A tiled display device comprising:
display devices; and
a seam portion between the display devices,
wherein one of the display devices comprises:
a substrate;
first electrodes above the substrate;
second electrodes above the substrate;
first pad electrodes respectively above the first electrodes;
second pad electrodes respectively above the second electrodes;
light-emitting elements respectively above the first pad electrodes and the second pad electrodes;
a first source voltage layer connected to the second electrodes; and
an electrostatic protection layer at an edge of at least one side of the substrate, and connected to the second pad electrodes and the first source voltage layer.

17. The tiled display device of claim 16, wherein the substrate comprises glass, and
wherein the display devices are arranged in a matrix form in M rows and N columns, M and N respectively being integers of 2 or more.

18. The tiled display device of claim 16, wherein the one of the display devices further comprises:
a side surface line on a side surface between a first surface of the substrate, and a second surface opposite to the first surface;
a bottom surface line on the second surface of the substrate; and
a circuit board connected to the bottom surface line through a conductive adhesive member.

19. An electronic device comprising a display device comprising:
a substrate;
first electrodes above the substrate;
second electrodes above the substrate;
first pad electrodes respectively above the first electrodes;
second pad electrodes respectively above the second electrodes;
light-emitting elements respectively above the first pad electrodes and the second pad electrodes;
a first source voltage layer connected to the second electrodes; and
an electrostatic protection layer at an edge of at least one side of the substrate, and connected to the second pad electrodes and to the first source voltage layer.

20. The electronic device of claim 19, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, a head-mounted display (HMD), a virtual reality (VR) device, or an augmented reality (AR) device.
